(19) United States
(12) Patent Application Publication
(10) Pub. No.: US 2003/0227311 A1
(43) Pub. Date: Dec. 11, 2003

(54) Analog CMOSFET switch with linear on resistance

(76) Inventor: Sumant Ranganathan, Sunnyvale, CA (US)

Correspondence Address: STERNE, KESSLER, GOLDSTEIN & FOX PLLC, 1100 NEW YORK AVENUE, N.W., WASHINGTON, DC, 20005, US

(21) Appl. No.: 10/377,023

(22) Filed: Mar. 3, 2003

Related U.S. Application Data
(60) Provisional application No. 60/360,180, filed on Mar. 1, 2002.

(51) Int. Cl. H03K 3/356; H03K 17/16

(52) U.S. Cl. 327/210; 327/214; 327/391; 327/437

(57) ABSTRACT

A CMOSFET switch includes a NMOSFET, a PMOSFET, an input formed at the connection of the source terminals of the MOSFETs, and an output formed at the connection of the drain terminals of the MOSFETs. At least one of the MOSFETs is characterized by a small magnitude inherent threshold voltage, or the CMOSFET switch has at least one circuit that is capable of reducing a voltage difference between the source and body terminals of a MOSFET, or both. The variations in on resistance can be reduced over a wide common mode range by reducing the threshold voltages of the NMOSFET and the PMOSFET of the CMOSFET switch.

### CROSS-REFERENCE TO RELATED APPLICATIONS

This application claims the benefit of U.S. Provisional Application No. 60/360,180, filed Mar. 1, 2002, which is incorporated herein by reference in its entirety.

### BACKGROUND OF THE INVENTION

1. Field of the Invention

The present invention relates to an analog CMOSFET switch with linear on resistance.

2. Background Art

In an integrated circuit (IC) fabricated using metal oxide semiconductor (MOS) processes, field effect transistors (MOSFETs) are often used as switches. This is particularly true in digital signal processing applications where switches realized as MOSFETs are used to convey an analog signal to various components of the processor such as, for example, a capacitor for sampling a voltage of the analog signal. Typically, two voltage potentials are used to power a MOS IC: a high voltage potential “V_{DD}” and a low voltage potential “V_{SS}”. (Alternatively, one of the voltage potentials can be ground.)

MOSFETs can be characterized by the type of doping used to produce the source and drain terminals. Where a MOSFET employs negatively doped regions formed on a positively doped substrate, the transistor is a NMOSFET. Conversely, where positively doped regions are formed on a negatively doped substrate, the device is a PMOSFET.

FIG. 1A is a schematic diagram of a circuit having a switch 102 realized using a NMOSFET 104. The circuit is powered by high voltage potential V_{DD} and low voltage potential V_{SS}. NMOSFET 104 is configured to receive an analog signal “vᵢ” at the source terminal of NMOSFET 104. In this configuration, NMOSFET 104 is typically turned ON by applying high voltage potential V_{DD} to the gate terminal of NMOSFET 104. Conversely, NMOSFET 104 is typically turned OFF by applying low voltage potential V_{SS} to the gate terminal of NMOSFET 104.

However, in order for NMOSFET 104 to conduct between its source and drain terminals, its drain-to-source voltage “V_{dsn}” must be greater than or equal to the sum of its gate-to-source voltage “V_{gsn}” and its threshold voltage “V_{Tn}” as shown in Eq. (1):

V_{dsn}≧V_{gsn}+V_{Tn}. Eq. (1)

Because of this requirement, the high voltage swing of analog signal vᵢ is constrained not to rise above the difference between high voltage potential V_{DD} and threshold voltage V_{Tn} as shown in Eq. (2):

v≦V_{DD}−V_{Tn}. Eq. (2)

FIG. 1B is a schematic diagram of a circuit having a switch 106 realized using a PMOSFET 108. PMOSFET 108 is configured to receive analog signal vᵢ at the source terminal of PMOSFET 108. In this configuration, PMOSFET 108 is typically turned ON by applying low voltage potential V_{SS} to the gate terminal of PMOSFET 108. Conversely, PMOSFET 108 is typically turned OFF by applying high voltage potential V_{DD} to the gate terminal of PMOSFET 108.

However, in order for PMOSFET 108 to conduct between its source and drain terminals, its drain-to-source voltage “V_{dsp}” must be less than or equal to the sum of its gate-to-source voltage “V_{gsp}” and its threshold voltage “V_{Tp}” (usually a negative voltage) as shown in Eq. (3):

V_{dsp}≦V_{gsp}+V_{Tp}. Eq. (3)

Because of this requirement, the low voltage swing of analog signal vᵢ is constrained not to drop below the difference between low voltage potential V_{SS} and threshold voltage V_{Tp} as shown in Eq. (4):

vᵢ≧V_{SS}−V_{Tp}. Eq. (4)

To avoid these constraints and facilitate circuits wherein analog signal vᵢ can swing from low voltage potential V_{SS} to high voltage potential V_{DD}, semiconductor manufacturing processes have evolved to support the formation of both NMOSFETs and PMOSFETs on a single substrate. These processes are referred to as complimentary metal oxide semiconductor (CMOS) technology.

FIG. 2 a cutaway, cross sectional view of a conventionally fabricated CMOSFET 200. CMOSFET 200 comprises NMOSFET 104 and PMOSFET 108. NMOSFET 104 comprises two negatively doped regions 202 and 204 embedded within a positively doped substrate 206. Regions 202 and 204 are separated by a first channel 208. An oxide layer 210 is deposited onto substrate 206 and partially covers regions 202 and 204. A metal is deposited onto oxide layer 210 opposite first channel 208 to form a first gate terminal 212 for NMOSFET 104. The metal is also deposited opposite region 202 to form a first source terminal 214, opposite region 204 to form a first drain terminal 216, and opposite substrate 206 to form a first body terminal 218 for NMOSFET 104.

For PMOSFET 108, a negatively doped well 220 is embedded within substrate 206. In turn, two positively doped regions 222 and 224 are embedded within well 220. Regions 222 and 224 are separated by a second channel 226. Oxide layer 210 is deposited onto well 220 and partially covers regions 222 and 224. A metal is deposited onto oxide layer 210 opposite second channel 226 to form a second gate terminal 228 for PMOSFET 108. The metal is also deposited opposite region 222 to form a second source terminal 230, opposite region 224 to form a second drain terminal 232, and opposite well 220 to form a second body terminal 234 for PMOSFET 108.

For each of NMOSFET 104 and PMOSFET 108, the channel is characterized by a length “L”, which measures the separation between the two doped regions, and a width “W” (not shown) perpendicular to the plane of FIG. 2. The ratio W/L is referred to as a “channel constant”.

Conversely, CMOSFET 200 could also be configured where PMOSFET 108 is formed on a negatively doped substrate and NMOSFET 104 is formed on a positively doped well embedded in the negatively doped substrate.

FIG. 3 is a schematic diagram of a circuit having a switch 302 realized using a CMOSFET 304. CMOSFET 304 comprises a parallel connection between NMOSFET 104 and PMOSFET 108. Source terminals 214 and 230 are together connected as an input 306. Drain terminals 216 and 232 are together connected as an output 308. Input 306 is configured to receive analog signal vᵢ. In this configuration, CMOSFET 304 is typically turned ON by applying high voltage potential V_{DD} to the gate terminal of NMOSFET 104 and low voltage potential V_{SS} to the gate terminal of PMOSFET 108. Advantageously, because parallel paths of conduction are provided through the parallel connection of NMOSFET 104 with PMOSFET 108, analog signal vᵢ can swing from low voltage potential V_{SS} to high voltage potential V_{DD}. CMOSFET 304 is typically turned OFF by applying low voltage potential V_{SS} to the gate terminal of NMOSFET 104 and high voltage potential V_{DD} to the gate terminal of PMOSFET 108.

However, employing CMOSFET 304 as a switch poses problems because when it is ON, its resistance—the “on resistance” (“Rₒₙ”)—is a function of the gate-to-source voltages as shown in Eq. (5):

Rₒₙ=1/{(μₙCₒₓWₙ/Lₙ)(V_{gsn}−V_{Tn}−V_{dsn})+(μₚCₒₓWₚ/Lₚ)(V_{gsp}−V_{Tp}−V_{dsp})}, Eq. (5)

where “Cₒₓ” is the gate oxide capacitance per unit area, “μₙ” is the average electron mobility in the channel for the NMOSFET, and “μₚ” is the average hole mobility in the channel for the PMOSFET. From Eq. (5) it follows that where a varying voltage (i.e., analog signal vᵢ) is applied to source terminals 214 and 230 while constant voltages (i.e., high voltage potential V_{DD} and low voltage potential V_{SS}) are applied to gate terminals 212 and 228, the gate-to-source voltages (i.e., V_{gsn} and V_{gsp}) vary. For this reason, on resistance Rₒₙ is essentially a non-linear function of analog signal vᵢ. Such non-linear variations in on resistance Rₒₙ act to distort the voltage of analog signal vᵢ as it is conducted across CMOSFET 304. This variation is usually measured in terms of total harmonic distortion (THD).

Further inspection of Eq. (5) suggests that on resistance Rₒₙ (and concomitantly the effects of variations in on resistance Rₒₙ) could be reduced by increasing the width (i.e., Wₙ and Wₚ) of the channels of NMOSFET 104 and PMOSFET 108. Unfortunately, while this approach does reduce on resistance Rₒₙ, it also increases junction capacitances, which also contribute to THD.

Often, applications require that THD be maintained within a given specification. In these situations, the THD specification, coupled with the frequency of analog signal vᵢ and the voltage potentials of V_{DD} and V_{SS}, dictates a limit to on resistance Rₒₙ. Yet, in order to facilitate allowing analog signal vᵢ to swing from low voltage potential V_{SS} to high voltage potential V_{DD}, the common mode voltage v_{cm} of analog signal vᵢ is usually set to a voltage potential midway between low voltage potential V_{SS} and high voltage potential V_{DD}. Unfortunately, setting common mode voltage v_{cm} to a voltage potential midway between low voltage potential V_{SS} and high voltage potential V_{DD} yields relatively small gate-to-source voltages (i.e., V_{gsn} and V_{gsp}), which in turn results in a relatively large on resistance Rₒₙ. (See, for example, curve 702 at FIG. 7.)

To mitigate the distortion caused by variations in on resistance Rₒₙ where a CMOSFET switch has a NMOSFET formed in the well of the CMOSFET, Stephen R. Norsworthy et al., Delta-Sigma Data Converters: Theory, Design, and Simulation, The Institute of Electrical and Electronics Engineers, Inc. 1997, which is incorporated herein by reference, teaches connecting second body terminal 234 (the body terminal of the transistor formed in well 220) to an appropriate voltage potential (e.g., low voltage potential V_{SS}) and charging a capacitor to an appropriate voltage potential (e.g., high voltage potential V_{DD}) when the CMOSFET switch is OFF, and connecting second body terminal 234 to second source terminal 230 and the capacitor between second source terminal 230 and second gate terminal 228 when the CMOSFET switch is ON. When the CMOSFET switch is ON, the charged capacitor acts to maintain the gate-to-source voltage v_{gsn} relatively constant, which in turn facilitates holding on resistance Rₒₙ relatively constant. Such a configuration is often referred to as using a “bootstrap” capacitor.

While the use of bootstrap capacitors has proven to be an adequate solution in many applications, it does present several disadvantages. Specifically, the bootstrap capacitors must be relatively large (on an order of magnitude that is four to five times the capacitance between the gate and source terminals of the CMOSFET switch), such that they consume substantial die area and dissipate a relatively large amount of power. What is needed is a mechanism that reduces the variations of the on resistance Rₒₙ of a CMOSFET switch while consuming less die area and dissipating less power. Preferably, such a mechanism would reduce the variations of the on resistance Rₒₙ over a wide range of settings for common mode voltage v_{cm}.

### BRIEF SUMMARY OF THE INVENTION

The present invention relates to an analog CMOSFET switch with linear on resistance. The present invention realizes that the variations of the on resistance (Rₒₙ) of a CMOSFET switch can be reduced over a wide common mode range by reducing the threshold voltages of the NMOSFET and the PMOSFET that comprise the CMOSFET.

In an embodiment, the CMOSFET switch includes a first MOSFET of a first polarity, a second MOSFET of a second polarity, an input, and an output. The first and second MOSFETs are connected in parallel. The first and second MOSFETs each have a source terminal, a drain terminal, and a body terminal. The input is formed at the connection of the source terminals of the first and second MOSFETs. The output is formed at the connection of the drain terminals of the first and second MOSFETs. The CMOSFET switch also comprises a first circuit and a second circuit. The first circuit is capable of reducing the difference in voltage between the source and body terminals of the first MOSFET. The second circuit is capable of reducing the difference in voltage between the source and body terminals of the second MOSFET. Optionally, the first MOSFET is characterized by a small magnitude inherent threshold voltage.

Preferably, the first circuit is a switching circuit that is capable of connecting the body terminal of the first MOSFET to its source terminal. The switching circuit can comprise a first switch and a second switch. The first switch is connected between the body and source terminals of the first MOSFET. The second switch is connected between the body terminal of the first MOSFET and a constant voltage potential. The first switch is ON when the CMOSFET switch is ON; the first switch is OFF when the CMOSFET switch is OFF. The second switch is ON when the CMOSFET switch is OFF; the second switch is OFF when the CMOSFET switch is ON. Preferably, the first switch is a second CMOSFET switch.

In another embodiment, instead of the first and second circuits, the first MOSFET is characterized by a first small magnitude inherent threshold voltage, and the second MOSFET is characterized by a second small magnitude inherent threshold voltage. Preferably, the first MOSFET is a native MOSFET. Optionally, the CMOSFET switch further comprises a circuit that is capable of reducing a difference in voltage between the source and body terminals of the first MOSFET.

In yet another embodiment, a circuit is capable of reducing the difference in voltage between the source and body terminals of the first MOSFET, while the second MOSFET is characterized by a small magnitude inherent threshold voltage. Preferably, the circuit is a switching circuit that is capable of connecting the body terminal of the first MOSFET to its source terminal. Preferably, the second MOSFET is a native MOSFET.

The present invention also encompasses a method of reducing an on resistance of a CMOSFET switch. In an embodiment, the method comprises reducing a difference in voltage between the source and body terminals of the first MOSFET of a first polarity of the CMOSFET, and reducing a difference in voltage between the source and body terminals of the second MOSFET of a second polarity of the CMOSFET.

In another embodiment, the method comprises fabricating a first MOSFET of a first polarity of the CMOSFET to have a first small magnitude inherent threshold voltage, and fabricating a second MOSFET of a second polarity of the CMOSFET to have a second small magnitude inherent threshold voltage.

In yet another embodiment, the method comprises fabricating a first MOSFET of a first polarity of the CMOSFET to have a small magnitude inherent threshold voltage, and reducing a difference in voltage between the source and body terminals of a second MOSFET of a second polarity of the CMOSFET.

The present invention also encompasses a switched sampling circuit. The switched sampling circuit comprises a CMOSFET switch and a sampling capacitor. The CMOSFET switch has an input and a switch output. The input is capable of receiving a signal. The sampling capacitor is connected to the switch output. At least one of the MOSFETs is characterized by a small magnitude inherent threshold voltage, or the CMOSFET switch has at least one supplemental circuit that is capable of reducing a voltage difference between the source and body terminals of a MOSFET, or both.

If the CMOSFET switch has a MOSFET that is characterized by a small magnitude inherent threshold voltage, preferably that MOSFET is a native MOSFET. If the CMOSFET switch has a supplemental circuit that is capable of reducing a voltage difference between the source and body terminals of a MOSFET, preferably that supplemental circuit is a switching circuit that is capable of connecting the body terminal of the MOSFET to its source terminal.

The present invention also encompasses a multiplexer. The multiplexer comprises a first switch, a second switch, and a selection circuit. The first switch has a first input and a first output. The first input is capable of receiving a first signal. The first switch is a CMOSFET switch. At least one of the MOSFETs of the CMOSFET switch is characterized by a small magnitude inherent threshold voltage, or the CMOSFET switch has at least one supplemental circuit that is capable of reducing a voltage difference between the source and body terminals of a MOSFET, or both. The second switch has a second input and a second output. The second input is capable of receiving a second signal. The second output is connected in parallel with the first output to form a multiplexer output. The selection circuit is capable of producing a selection that can turn ON one of the first switch and the second switch.

If the CMOSFET switch has a MOSFET that is characterized by a small magnitude inherent threshold voltage, preferably that MOSFET is a native MOSFET. If the CMOSFET switch has a supplemental circuit that is capable of reducing a voltage difference between the source and body terminals of a MOSFET, preferably that supplemental circuit is a switching circuit that is capable of connecting the body terminal of the MOSFET to its source terminal.

### BRIEF DESCRIPTION OF THE FIGURES

The accompanying drawings, which are incorporated herein and form part of the specification, illustrate the present invention and, together with the description, further serve to explain the principles of the invention and to enable a person skilled in the pertinent art to make and use the invention.

FIG. 1A is a schematic diagram of a circuit having a switch 102 realized using a NMOSFET 104.

FIG. 1B is a schematic diagram of a circuit having a switch 106 realized using a PMOSFET 108.

FIG. 2 a cutaway, cross sectional view of a conventionally fabricated CMOSFET 200.

FIG. 3 is a schematic diagram of a circuit having a switch 302 realized using a CMOSFET 304.

FIG. 4 is a schematic diagram of a circuit having a switch 402 realized using a CMOSFET 404 configured in the manner of the present invention.

FIG. 5 is a schematic diagram of a circuit having a switch 502 realized using a CMOSFET 504 configured in the manner of the present invention.

FIG. 6 is a schematic diagram of a circuit having a switch 602 realized using a CMOSFET 604 configured in the manner of the present invention.

FIG. 7 is a graph 700 of on resistance Rₒₙ versus common mode voltage v_{cm} for variously configured CMOSFET switches.

FIG. 8 shows a flow chart of a method 800 of reducing an on resistance of a CMOSFET switch in the manner of the present invention.

FIG. 9 shows a flow chart of a method 900 of reducing an on resistance of a CMOSFET switch in the manner of the present invention.

FIG. 10 shows a flow chart of a method 1000 of reducing an on resistance of a CMOSFET switch in the manner of the present invention.

FIG. 11 is a block diagram of a switched sampling circuit 1100 in the manner of the present invention.

FIG. 12 is a block diagram of a multiplexer 1200 in the manner of the present invention.

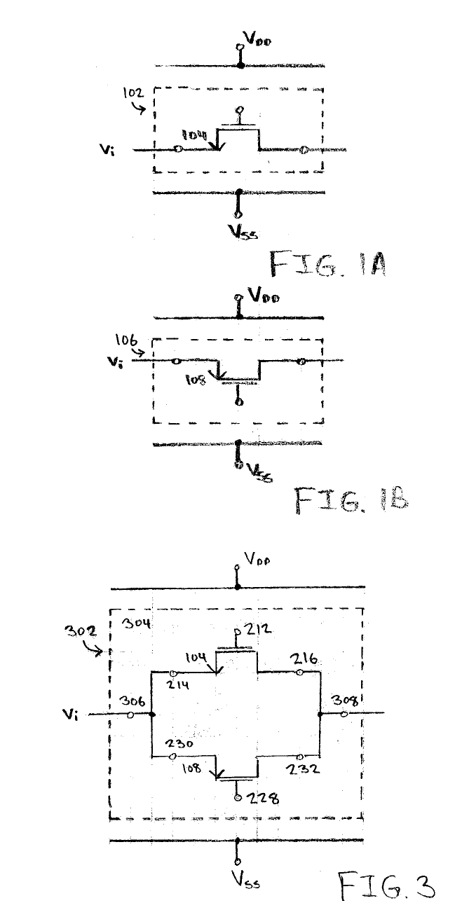

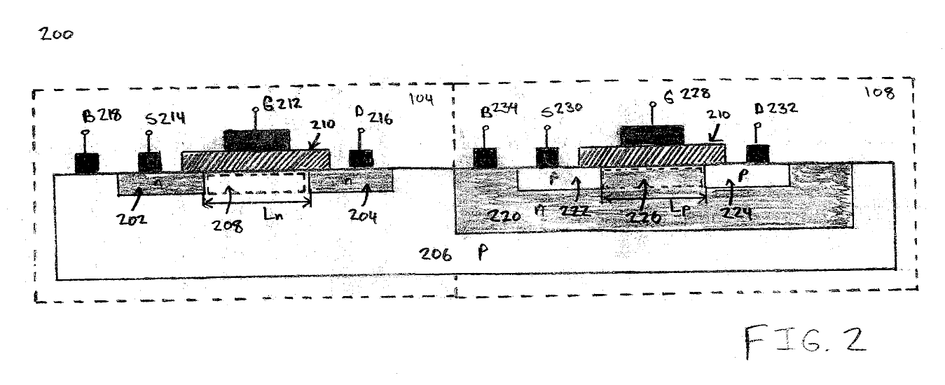

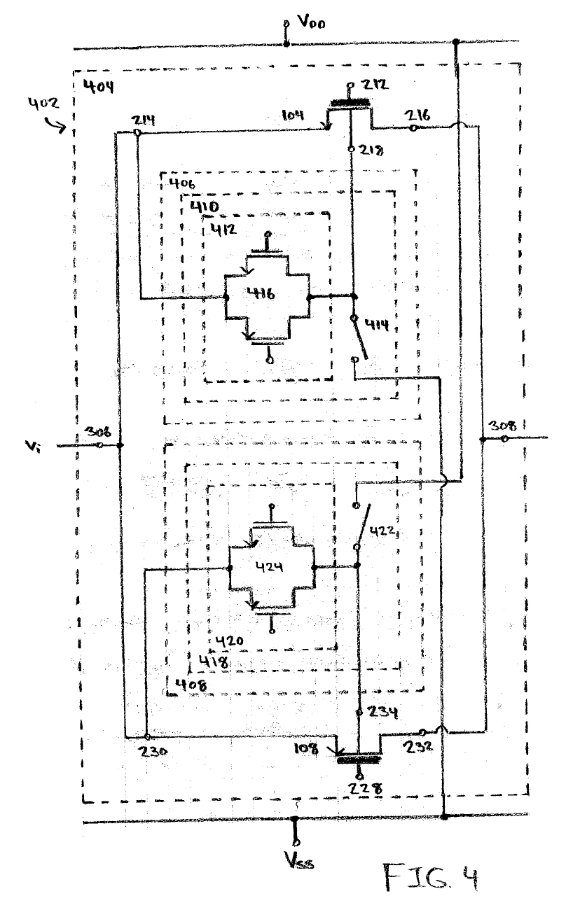

The preferred embodiments of the invention are described with reference to the figures where like reference numbers indicate identical or functionally similar elements. Also in the figures, the left most digit of each reference number identifies the figure in which the reference number is first used.

### DETAILED DESCRIPTION OF THE INVENTION

Introduction

The present invention relates to an analog CMOSFET switch with linear on resistance. The on resistance Rₒₙ of a CMOSFET switch is, as shown in Eq. (5), a function of the gate-to-source voltages, the drain-to-source voltages, and the threshold voltages of the NMOSFET and the PMOSFET that comprise the CMOSFET. When a signal having a varying voltage is applied to the source terminals of the NMOSFET and the PMOSFET while their gate terminals are held at constant voltages, on resistance Rₒₙ becomes essentially a non-linear function of the applied signal. Such non-linear variations in on resistance Rₒₙ act to distort the voltage of the applied signal as it is conducted across the CMOSFET switch.

The present invention recognizes that the threshold voltage V_{T} of a MOSFET is a function of its source-to-body voltage as shown in Eq. (6):

V_{T}=V_{T0}+γ{(2φ_{f}+V_{SB})^{1/2}−(2φ_{f})^{1/2}}, Eq. (6)

where “V_{T0}” is the inherent threshold voltage of the MOSFET, “γ” is a (process dependent) threshold voltage parameter, “φ_{f}” is the Fermi potential of the junction, and “V_{SB}” is the large signal voltage potential between the source and body terminals.

The present invention further recognizes that when a signal having a varying voltage is applied to the source terminals of the NMOSFET and the PMOSFET while their body terminals are held at constant voltages, the threshold voltages of the NMOSFET and the PMOSFET also vary, and that the variations of these threshold voltages contribute significantly to the variations of on resistance Rₒₙ.

The present invention realizes that, by reducing the threshold voltages of the NMOSFET and the PMOSFET that comprise a CMOSFET switch, the variations of its on resistance Rₒₙ can be reduced over a wide range of settings for a common mode voltage of an applied analog signal.

Circuit Embodiments

FIG. 4 is a schematic diagram of a circuit having a switch 402 realized using a CMOSFET 404 configured in the manner of the present invention. CMOSFET 404 comprises a parallel connection between NMOSFET 104 and PMOSFET 108. Source terminals 214 and 230 are together connected as input 306. Drain terminals 216 and 232 are together connected as output 308. Input 306 is configured to receive analog signal vᵢ.

CMOSFET 404 also comprises a first circuit 406 and a second circuit 408. First circuit 406 is capable of reducing the difference in voltage between source terminal 214 and body terminal 218 of NMOSFET 104. Second circuit 408 is capable of reducing the difference in voltage between source terminal 230 and body terminal 234 of PMOSFET 108. Optionally, NMOSFET 104, PMOSFET 108, or both can be characterized by a small magnitude inherent threshold voltage.

Preferably, first circuit 406 is a first switching circuit 410 that is capable of connecting body terminal 218 to source terminal 214. First switching circuit 410 can comprise a first switch 412 and a second switch 414. First switch 412 is connected between body terminal 218 and source terminal 214. Preferably, first switch 412 is a second CMOSFET switch 416. Second switch 414 is connected between body terminal 218 and a low voltage potential such as, for example, low voltage potential VSS. First switch 412 is ON when CMOSFET switch 402 is ON; first switch 412 is OFF when CMOSFET switch 402 is OFF. Second switch 414 is ON when CMOSFET switch 402 is OFF; second switch 414 is OFF when CMOSFET switch 402 is ON.

Likewise, second circuit 408 is preferably a second switching circuit 418 that is capable of connecting body terminal 234 to source terminal 230. Second switching circuit 418 can comprise a third switch 420 and a fourth switch 422. Third switch 420 is connected between body terminal 234 and source terminal 230. Preferably, third switch 420 is a third CMOSFET switch 424. Fourth switch 422 is connected between body terminal 234 and a high voltage potential such as, for example, high voltage potential V_{DD}. Third switch 420 is ON when CMOSFET switch 402 is ON; third switch 420 is OFF when CMOSFET switch 402 is OFF. Fourth switch 422 is ON when CMOSFET switch 402 is OFF; fourth switch 422 is OFF when CMOSFET switch 402 is ON.

An enhancement MOSFET operates by establishing a voltage potential between its gate and body. NMOSFET 104 is typically turned ON by applying a high voltage potential, such as high voltage potential V_{DD}, to gate terminal 212. Conversely, NMOSFET 104 is typically turned OFF by applying a low voltage potential, such as low voltage potential V_{SS}, to gate terminal 212. This operation assumes that body terminal 218 is held at a low voltage potential, such as low voltage potential V_{SS}. Likewise, PMOSFET 108 is typically turned ON by applying a low voltage potential, such as low voltage potential V_{SS}, to gate terminal 228. Conversely, PMOSFET 108 is typically turned OFF by applying a high voltage potential, such as high voltage potential V_{DD}, to gate terminal 228. Again, this operation assumes that body terminal 234 is held at a high voltage potential, such as high voltage potential V_{DD}.

Where a MOSFET is formed on a substrate, often it is not necessary to connect the body terminal to a constant voltage potential. However, where a MOSFET is formed on a well imbedded in a substrate, it is usually prudent, owing the junction that exists between the well and the substrate, to connect the body terminal to a constant voltage potential.

When a signal having a varying voltage (i.e., analog signal vᵢ) is applied to the source terminal of a MOSFET while its body terminal is held at a constant voltage potential, the threshold voltage V_{T} of the MOSFET varies as shown by application of Eq. (6). Furthermore, by application of Eq. (5), the variations in the threshold voltage contribute to variations in the on resistance Rₒₙ. Thus, by reducing the difference in voltage between source terminal 214 and body terminal 218 and the difference in voltage between source terminal 230 and body terminal 234, first and second circuits 406 and 408 act to reduce the variations in on resistance Rₒₙ.

Where, for example, first circuit 406 is realized as first switching circuit 410 that can connect body terminal 218 to source terminal 214, the difference in voltage between source terminal 214 and body terminal 218 is reduced to zero. In this case, from Eq. (6), threshold voltage V_{Tn} of NMOSFET 104 is reduced to V_{Tn0}, the inherent threshold voltage of NMOSFET 104. Likewise, where, for example, second circuit 408 is realized as second switching circuit 418 that can connect body terminal 234 to source terminal 230, the difference in voltage between source terminal 230 and body terminal 234 is reduced to zero so that threshold voltage V_{Tp} of PMOSFET 108 is reduced to V_{Tp0}, the inherent threshold voltage of PMOSFET 108.

Where, for example, first switching circuit 410 has first switch 412 connected between body terminal 218 and source terminal 214, first switch 412 preferably is realized as second CMOSFET switch 416. Having first switch 412 realized as second CMOSFET switch 416 allows first switch 412 to conduct analog signal vᵢ as it swings from low voltage potential V_{SS} to high voltage potential V_{DD}. Second CMOSFET switch 416 can be configured in a manner similar to CMOSFET switch 302. Likewise, third switch 420 can preferably be realized as third CMOSFET switch 424 to conduct analog signal vᵢ as it swings from low voltage potential V_{SS} to high voltage potential V_{DD}.

Furthermore, it is advantageous for first switching circuit 410 to include second switch 414 connected between body terminal 218 and a low voltage potential, such as low voltage potential VSS. Second switch 414 acts to reduce the voltage potential between gate terminal 212 and body terminal 218 so that NMOSFET 104 does not conduct when CMOSFET switch 402 is OFF. NMOSFET 104 is typically turned OFF by applying a low voltage potential, such as low voltage potential V_{SS}, to gate terminal 212. Second switch 414 is ON when CMOSFET switch 402 (including NMOSFET 104) is OFF. Likewise, it is advantageous for second switching circuit 418 to include fourth switch 422 connected between body terminal 234 and a high voltage potential, such as high voltage potential V_{DD}. Fourth switch 422 acts to reduce the voltage potential between gate terminal 228 and body terminal 234 so that PMOSFET 108 does not conduct when CMOSFET switch 402 is OFF. PMOSFET 108 is typically turned OFF by applying a high voltage potential, such as high voltage potential V_{DD}, to gate terminal 228. Fourth switch 422 is ON when CMOSFET switch 402 (including PMOSFET 108) is OFF.

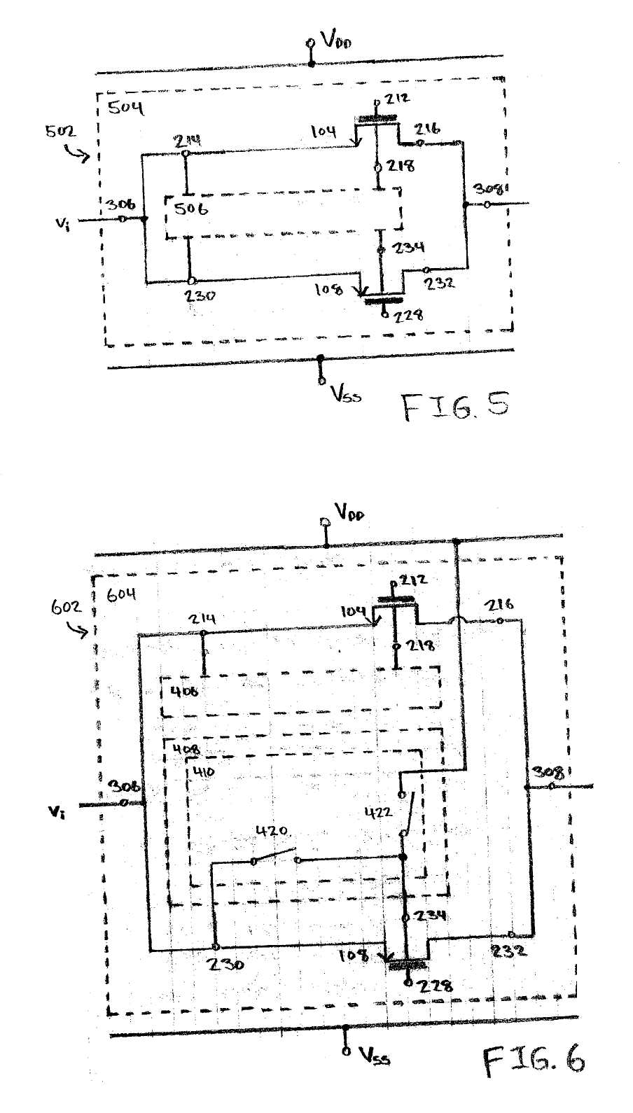

FIG. 5 is a schematic diagram of a circuit having a switch 502 realized using a CMOSFET 504 configured in the manner of the present invention. CMOSFET 504 comprises a parallel connection between NMOSFET 104 and PMOSFET 108. Source terminals 214 and 230 are together connected as input 306. Drain terminals 216 and 232 are together connected as output 308. Input 306 is configured to receive analog signal vᵢ. In CMOSFET 504, NMOSFET 104 is characterized by a first small magnitude inherent threshold voltage, and PMOSFET 108 is characterized by a second small magnitude inherent threshold voltage. Preferably, NMOSFET 104, PMOSFET 108, or both are native MOSFETs. A native MOSFET is characterized as having an inherent threshold voltage near zero. Optionally, CMOSFET switch 502 can further comprises a circuit 506 that is capable of reducing a difference in voltage between source terminal 214 and body terminal 218, between source terminal 230 and body terminal 234, or both. For example, circuit 506 can be realized as first circuit 406, second circuit 408, or both.

By application of Eq. (6), a small magnitude inherent threshold voltage V_{T0} reduces the magnitude of the threshold voltage V_{T}, which by application of Eq. (5) reduces the magnitude of on resistance Rₒₙ (and concomitantly the effects of variations in on resistance Rₒₙ). Thus, reducing the magnitude of inherent threshold voltage V_{T0n} of NMOSFET 104, the magnitude of inherent threshold voltage V_{T0p} of PMOSFET 108, or both acts to reduce the variations in on resistance Rₒₙ.

FIG. 6 is a schematic diagram of a circuit having a switch 602 realized using a CMOSFET 604 configured in the manner of the present invention. CMOSFET 604 comprises a parallel connection between NMOSFET 104 and PMOSFET 108. Source terminals 214 and 230 are together connected as input 306. Drain terminals 216 and 232 are together connected as output 308. Input 306 is configured to receive analog signal vᵢ. In CMOSFET 604, NMOSFET 104 is characterized by a small magnitude inherent threshold voltage. Preferably, NMOSFET 104 is a native MOSFET. CMOSFET 604 also comprises circuit 408 that is capable of reducing the difference in voltage between source terminal 230 and body terminal 234 of PMOSFET 108. Preferably, circuit 408 is switching circuit 410 that is capable of connecting body terminal 234 to source terminal 230. Alternatively, CMOSFET 604 can be configured with circuit 406 that is capable of reducing the difference in voltage between source terminal 214 and body terminal 218 of NMOSFET 104 and with PMOSFET 108 characterized by a small magnitude inherent threshold voltage.

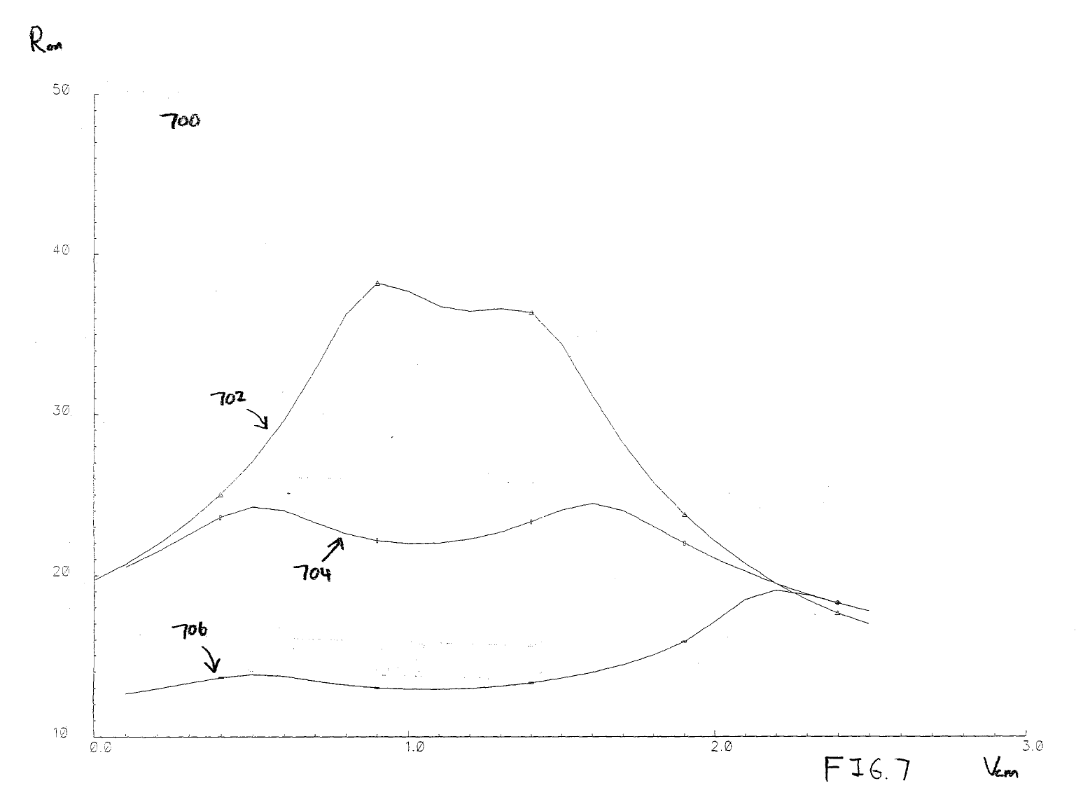

FIG. 7 is a graph 700 of on resistance Rₒₙ versus common mode voltage v_{cm} for variously configured CMOSFET switches. Graph 700 relates to an application in which low voltage potential V_{SS} is set to ground and high voltage potential V_{DD} is set to three volts. In graph 700, a curve 702 shows on resistance Rₒₙ versus common mode voltage v_{cm} for CMOSFET switch 302; a curve 704 shows on resistance Rₒₙ versus common mode voltage v_{cm} for CMOSFET switch 402; and a curve 706 shows on resistance Rₒₙ versus common mode voltage v_{cm} for a configuration of CMOSFET switch 602 in which NMOSFET 104 is the native MOSFET.

Curve 702 shows the large degree of variation of on resistance Rₒₙ with common mode voltage v_{cm} associated with CMOSFET switch 302. Particularly, curve 702 shows the large magnitude of on resistance Rₒₙ when common mode voltage v_{cm} is set to a voltage potential midway between low voltage potential V_{SS} and high voltage potential V_{DD}. Curves 704 and 706 show how variations in on resistance Rₒₙ with common mode voltage v_{cm} are improved by the present invention.

Method Embodiments

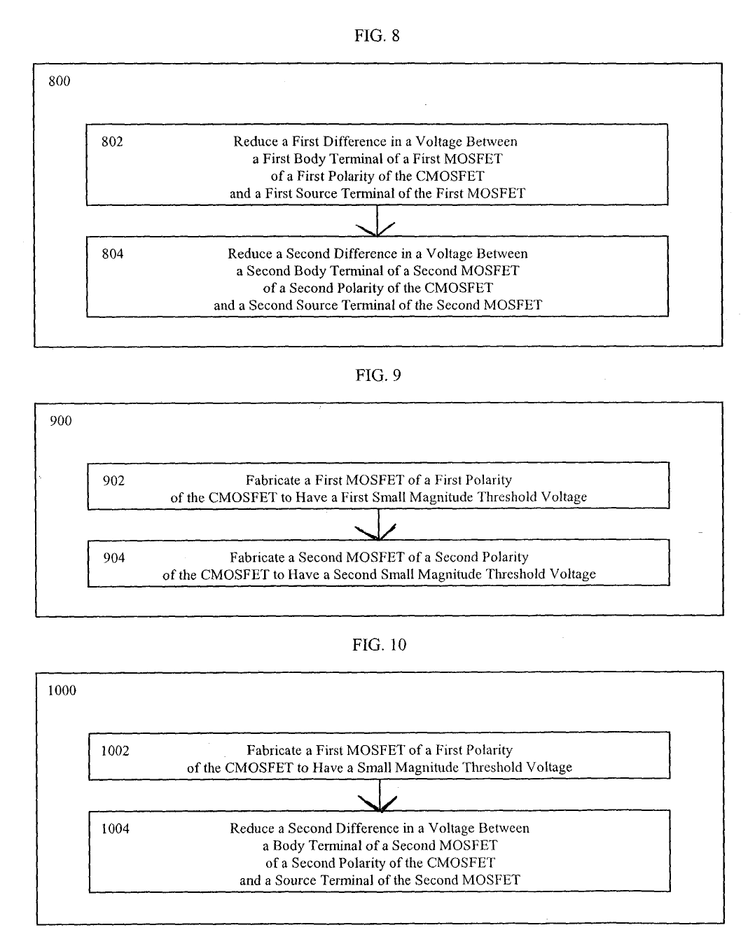

FIG. 8 shows a flow chart of a method 800 of reducing an on resistance of a CMOSFET switch in the manner of the present invention. In method 800, at a step 802, a first difference in voltage between a first body terminal of a first MOSFET of a first polarity of the CMOSFET and a first source terminal of the first MOSFET is reduced. For example, a first switching circuit can be used to connect the body terminal of the first MOSFET to its source terminal. At a step 804, a second difference in voltage between a second body terminal of a second MOSFET of a second polarity of the CMOSFET and a second source terminal of the second MOSFET is reduced. For example, a second switching circuit can be used to connect the body terminal of the second MOSFET to its source terminal.

FIG. 9 shows a flow chart of a method 900 of reducing an on resistance of a CMOSFET switch in the manner of the present invention. In method 900, at a step 902, a first MOSFET of a first polarity of the CMOSFET is fabricated to have a first small magnitude inherent threshold voltage. For example, the first MOSFET can be fabricated as a native MOSFET. At a step 904, a second MOSFET of a second polarity of the CMOSFET is fabricated to have a second small magnitude inherent threshold voltage. For example, the second MOSFET can be fabricated as a native MOSFET.

FIG. 10 shows a flow chart of a method 1000 of reducing an on resistance of a CMOSFET switch in the manner of the present invention. In method 1000, at a step 1002, a first MOSFET of a first polarity of the CMOSFET is fabricated to have a small magnitude inherent threshold voltage. For example, the first MOSFET can be fabricated as a native MOSFET. At a step 1004, a difference in voltage between a body terminal of a second MOSFET of a second polarity of the CMOSFET and a source terminal of the second MOSFET is reduced. For example, a switching circuit can be used to connect the body terminal of the second MOSFET to its source terminal.

By limiting variations in on resistance Rₒₙ, the present invention can, for a given specification of total harmonic distortion (THD) and voltage potentials of V_{DD} and V_{SS}, allow the CMOSFET switch to conduct an analog signal having a larger amplitude or frequency. Conversely, if the amplitude or frequency of the analog signal are held to their original limitations, the THD specification of the CMOSFET switch can be improved.

Switched Sampling Circuit

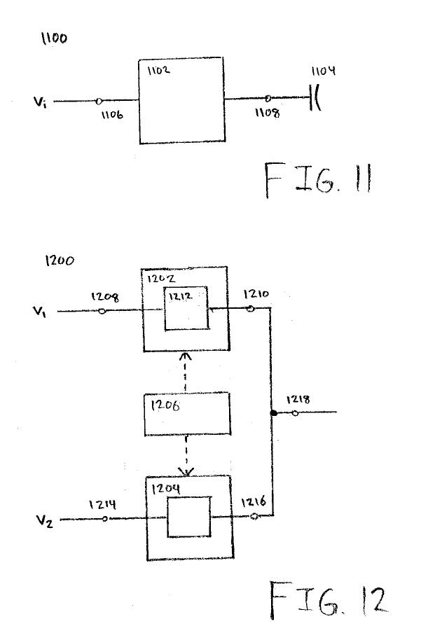

FIG. 11 is a block diagram of a switched sampling circuit 1100 in the manner of the present invention. Switched sampling circuit 1100 comprises a CMOSFET switch 1102 and a capacitor 1104. CMOSFET switch 1102 has an input 1106 and a switch output 1108. Input 1106 is capable of receiving a signal vᵢ. CMOSFET switch 1102 can be any of CMOSFET switch 402, CMOSFET switch 502, or CMOSFET switch 602.

If CMOSFET switch 1102 has a MOSFET that is characterized by a small magnitude inherent threshold voltage, preferably that MOSFET is a native MOSFET. If CMOSFET switch 1102 has a supplemental circuit that is capable of reducing a voltage difference between the source and body terminals of a MOSFET, preferably that supplemental circuit is a switching circuit that is capable of connecting the body terminal of the MOSFET to its source terminal.

When CMOSFET 1102 is ON, it conducts signal vᵢ to capacitor 1104, which charges to a voltage that corresponds to the instantaneous voltage of signal vᵢ. When CMOSFET 1102 is turned OFF, capacitor 1104 ceases being charged so that the stored voltage constitutes a sample of signal vᵢ.

Multiplexer

FIG. 12 is a block diagram of a multiplexer 1200 in the manner of the present invention. Multiplexer 1200 comprises a first switch 1202, a second switch 1204, and a selection circuit 1206. First switch 1202 has a first input 1208 and a first output 1210. First input 1208 is capable of receiving a first signal v₁. First switch 1202 is a CMOSFET switch 1212. CMOSFET switch 1212 can be any of CMOSFET switch 402, CMOSFET switch 502, or CMOSFET switch 602. Second switch 1204 has a second input 1214 and a second output 1216. Second input 1214 is capable of receiving a second signal v₂. Second switch 1204 can also be a CMOSFET switch, preferably configured in the same manner as CMOSFET switch 1212. Second output 1216 is connected in parallel with first output 1210 to form a multiplexer output 1218. Selection circuit 1206 is capable of producing a selection that can turn ON one of first switch 1202 and second switch 1204.

If CMOSFET switch 1212 has a MOSFET that is characterized by a small magnitude inherent threshold voltage, preferably that MOSFET is a native MOSFET. If CMOSFET switch 1212 has a supplemental circuit that is capable of reducing a voltage difference between the source and body terminals of a MOSFET, preferably that supplemental circuit is a switching circuit that is capable of connecting the body terminal of the MOSFET to its source terminal.

When selection circuit 1206 produces a selection that turns ON first switch 1202, first signal v₁ is conducted by first switch 1202 from first input 1208 to multiplexer output 1218. When selection circuit 1206 produces a selection that turns ON second switch 1204, second signal v₂ is conducted by second switch 1204 from second input 1214 to multiplexer output 1218.

Conclusion

While various embodiments of the present invention have been described above, it should be understood that they have been presented by way of example, and not limitation. It will be apparent to persons skilled in the relevant art that various changes in form and detail can be made therein without departing from the spirit and scope of the invention. Thus the present invention should not be limited by any of the above-described exemplary embodiments, but should be defined only in accordance with the following claims and their equivalents.

What is claimed is:

1. A complementary metal oxide semiconductor field effect transistor (CMOSFET) switch, comprising:
a first MOSFET of a first polarity having a first source terminal, a first drain terminal, and a first body terminal;
a second MOSFET of a second polarity having a second source terminal, a second drain terminal, and a second body terminal, said second MOSFET connected in parallel with said first MOSFET;
an input formed at a first connection of said first source terminal with said second source terminal;
an output formed at a second connection of said first drain terminal with said second drain terminal;
a first circuit that is capable of reducing a first difference in voltage between said first source terminal and said first body terminal; and
a second circuit that is capable of reducing a second difference in voltage between said second source terminal and said second body terminal.

2. The CMOSFET switch of claim 1, wherein said first MOSFET is a NMOSFET and said second MOSFET is a PMOSFET.

3. The CMOSFET switch of claim 1, wherein said first MOSFET is a PMOSFET and said second MOSFET is a NMOSFET.

4. The CMOSFET switch of claim 1, wherein said first circuit is a switching circuit that is capable of connecting said first body terminal to said first source terminal.

5. The CMOSFET switch of claim 4, wherein said switching circuit comprises:
a first switch connected between said first body terminal and said first source terminal; and
a second switch connected between said first body terminal and a constant voltage potential;
wherein:
said first switch is ON when the CMOSFET switch is ON;
said first switch is OFF when the CMOSFET switch is OFF;
said second switch is ON when the CMOSFET switch is OFF; and
said second switch is OFF when the CMOSFET switch is ON.

6. The CMOSFET switch of claim 5, wherein said first switch is a second CMOSFET switch.

7. The CMOSFET switch of claim 1, wherein said first MOSFET is characterized by a small magnitude inherent threshold voltage.

8. A complementary metal oxide semiconductor field effect transistor (CMOSFET) switch, comprising:
a first MOSFET of a first polarity having a first source terminal and a first drain terminal, said first MOSFET characterized by a first small magnitude inherent threshold voltage;
a second MOSFET of a second polarity having a second source terminal and a second drain terminal, said second MOSFET characterized by a second small magnitude inherent threshold voltage, said second MOSFET connected in parallel with said first MOSFET;
an input formed at a first connection of said first source terminal with said second source terminal; and
an output formed at a second connection of said first drain terminal with said second drain terminal.

9. The CMOSFET switch of claim 8, wherein said first MOSFET is a NMOSFET and said second MOSFET is a PMOSFET.

10. The CMOSFET switch of claim 8, wherein said first MOSFET is a PMOSFET and said second MOSFET is a NMOSFET.

11. The CMOSFET switch of claim 8, wherein said first MOSFET is a native MOSFET.

12. The CMOSFET switch of claim 11, further comprising:
a circuit that is capable of reducing a difference in voltage between said first source terminal and a body terminal of said first MOSFET.

13. A complementary metal oxide semiconductor field effect transistor (CMOSFET) switch, comprising:
a first MOSFET of a first polarity having a first source terminal, a first drain terminal, and a body terminal;
a second MOSFET of a second polarity having a second source terminal and a second drain terminal, said second MOSFET characterized by a small magnitude inherent threshold voltage, said second MOSFET connected in parallel with said first MOSFET;
an input formed at a first connection of said first source terminal with said second source terminal;
an output formed at a second connection of said first drain terminal with said second drain terminal; and
a circuit that is capable of reducing a difference in voltage between said first source terminal and said body terminal.

14. The CMOSFET switch of claim 13, wherein said first MOSFET is a NMOSFET and said second MOSFET is a PMOSFET.

15. The CMOSFET switch of claim 13, wherein said first MOSFET is a PMOSFET and said second MOSFET is a NMOSFET.

16. The CMOSFET switch of claim 13, wherein said first MOSFET is a native MOSFET.

17. The CMOSFET switch of claim 16, wherein said circuit is a switching circuit that is capable of connecting said first body terminal to said first source terminal.

18. A method of reducing an on resistance of a complementary metal oxide semiconductor field effect transistor (CMOSFET) switch, comprising:
(1) reducing a first difference in voltage between a first body terminal of a first MOSFET of a first polarity of the CMOSFET and a first source terminal of the first MOSFET; and
(2) reducing a second difference in voltage between a second body terminal of a second MOSFET of a second polarity of the CMOSFET and a second source terminal of the second MOSFET.

19. A method of reducing an on resistance of a complementary metal oxide semiconductor field effect transistor (CMOSFET) switch, comprising:
(1) fabricating a first MOSFET of a first polarity of the CMOSFET to have a first small magnitude inherent threshold voltage; and
(2) fabricating a second MOSFET of a second polarity of the CMOSFET to have a second small magnitude inherent threshold voltage.

20. A method of reducing an on resistance of a complementary metal oxide semiconductor field effect transistor (CMOSFET) switch, comprising:
(1) fabricating a first MOSFET of a first polarity of the CMOSFET to have a small magnitude inherent threshold voltage; and
(2) reducing a difference in voltage between a body terminal of a second MOSFET of a second polarity of the CMOSFET and a source terminal of the second MOSFET.

21. A switched sampling circuit, comprising:
a complementary metal oxide semiconductor field effect transistor (CMOSFET) switch having an input capable of receiving a signal, a switch output, and at least one of a MOSFET characterized by a small magnitude inherent threshold voltage, and a supplemental circuit that is capable of reducing a voltage difference between a source terminal of said MOSFET and a body terminal of a said MOSFET; and
a sampling capacitor connected to said switch output.

22. The switched sampling circuit of claim 21, wherein said MOSFET is a native MOSFET.

23. The switched sampling circuit of claim 21, wherein said supplemental circuit is a switching circuit that is capable of connecting said body terminal to said source terminal.

24. A multiplexer, comprising:
a first switch, said first switch being a complementary metal oxide semiconductor field effect transistor (CMOSFET) switch having a first input capable of receiving a first signal, a first output, and at least one of a MOSFET characterized by a small magnitude inherent threshold voltage, and a supplemental circuit that is capable of reducing a voltage difference between a source terminal of said MOSFET and a body terminal of a said MOSFET;
a second switch having a second input capable of receiving a second signal, and a second output connected in parallel with said first output to form a multiplexer output; and
a selection circuit that is capable of producing a selection that can turn ON one of said first switch and said second switch.

25. The multiplexer of claim 24, wherein said MOSFET is a native MOSFET.

26. The multiplexer of claim 24, wherein said supplemental circuit is a switching circuit that is capable of connecting said body terminal to said source terminal.
